(19) United States
(12) Patent Application Publication
(10) Pub. No.: US 2008/0057727 A1
(43) Pub. Date: Mar. 6, 2008

(54) METHOD OF MANUFACTURING A SEMICONDUCTOR DEVICE

(75) Inventor: Hidetaka NANBU, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/842,989

(22) Filed: Aug. 22, 2007

(30) Foreign Application Priority Data
Aug. 30, 2006 (JP) 2006-233156
Jun. 18, 2007 (JP) 2007-159950

(51) Int. Cl. H01L 21/302

(52) U.S. Cl. 438/719; 257/E21.214

(57) ABSTRACT

Method of manufacturing a semiconductor device including arranging a substrate having a stacked film containing a first insulating film and a second insulating film formed thereon in an etching equipment, etching the first and second insulating film in the etching equipment, the first insulating film comprised of a nitrogen-containing film, and the second insulating film comprised of one or more kinds of films selected from a group consisting of an SiOCH film, an SiO₂ film, a methyl silsesquioxane film, a hydrogen silsesquioxane film and a methyl hydrogen silsesquioxane film, while using as etching gas (a) gas including fluorocarbon represented by CxFy (x: an integer from 1 to 6, and y: an integer from 4 to 12), or (b) mixed gas of the fluorocarbon and one or more kinds of gas selected from a group consisting of O₂, Ar and CO.

This application is based on Japanese patent application Nos. 2006-233156 and 2007-159950, the contents of which are incorporated hereinto by reference.

### BACKGROUND

1. Technical Field

The present invention relates to a method of manufacturing a semiconductor device, including steps at which a stacked film is etched in one and the same etching equipment.

2. Related Art

Recently, a processing method using a so-called all-in-one etching method in which a plurality of etching steps are performed in one and the same equipment has become mainstream in order to suppress the manufacturing cost of a semiconductor device (refer to Japanese Laid-Open Patent Publication Nos. 2003-45964, 2003-309107, and 2005-353698).

Moreover, Japanese Laid-Open Patent Publication No. 2003-45964 has disclosed an example in which a dual damascene structure is formed according to the all-in-one etching technique, using an organic material as an interlayer insulating film. However, the organic material is generally expensive. Thereby, in recent years, an inorganic material with an Si—C bonding has been used for an interlayer insulating film formed by plasma CVD.

Japanese Laid-Open Patent Publication No. 2005-353698 has disclosed an all-in-one etching method using an inorganic interlayer film, by which a chamber is cleaned between etching steps to remove a deposit because a polymer containing a carbon atom and a hydrogen atom is deposited in the chamber. Specifically, a stacked substrate, in which a silicon nitride film 54, a silicon oxide film 56, and a resist film 58 provided with an opening having a predetermined pattern are sequentially stacked on a substrate 52 in this order, is mounted in a chamber 50 of an etching equipment, as shown in FIG. 10A, to etch a silicon oxide film 56 by plasma etching. In this case, a deposit 60 is adhered to the inner wall of the chamber 50 in the etching equipment (FIG. 10B). Plasma cleaning is executed in order to remove the above deposit 60, and, subsequently, the silicon nitride film 54 is etched (FIG. 10C).

A CHF₃ containing gas is listed as an etching gas for a layer including SiC or SiCN in Japanese Laid-Open Patent Publication No. 2004-296835.

### SUMMARY

However, there has been left room for improvement in the conventional technology disclosed in Japanese Laid-Open Patent Publication No. 2005-353698 as shown in the following description.

Even if the cleaning step is provided as described in the above patent document, the deposit adhered to the inner wall of the chamber can be not completely removed. Thereby, there has been a case in which, when a plurality of wafers are continuously processed in one and the same chamber, etching characteristics are influenced by deposits at an etching step for to be processed later. Accordingly, there have been some problems in which there are caused variations in etching depths of via holes, interconnect trenches, and the like between wafers and within a same wafer to increase interconnect resistances, contact resistances, and the like.

The above problems will be explained as follows, referring to drawings.

As shown in FIG. 4A, a wafer 37 is mounted in a chamber of an etching equipment 32 provided with an upper electrode 34 and a lower electrode 36. Then, a predetermined voltage is applied to between the upper electrode 34 and the lower electrode 36, and a target film is etched, using etching gas as plasma 38. An SiCN film is used as a target film, and CF₄/N₂ (or CH₂F₂/CF₄/Ar/O₂) is adopted as etching gas. In the above etching step, a deposit 40 adheres to the inner wall of the chamber 32. When all etching steps for the wafer 37 are completed, etching steps for another wafer 42 are subsequently performed. Here, CF₄/N₂ means mixed gas of CF₄ and N₂.

As shown in FIG. 4B, the another wafer 42 is mounted in the chamber of the etching equipment 32 in a similar manner to that of FIG. 4A. Then, a predetermined voltage is applied to between the upper electrode 34 and the lower electrode 36, and a target film is etched, using etching gas as plasma 38. An SiOCH film is used as a target film, and CF₄/N₂ (or CH₂F₂/CF₄/Ar/O₂) is adopted as etching gas. In the above etching step, a deposit 40, which has adhered to the inner wall of the chamber 32, is re-dissociated, and a nitrogen atom in the deposit 40 (or a hydrogen atom) is mixed with the etching gas. Thereby, it may be considered that nitrogen gas concentration (or hydrogen gas concentration) in the vicinity of the inner wall of the chamber 32 is increased to improve an etching grade on the outer edge of the wafer 42.

It is found as a result of examinations by the present inventor that, as described above, the method of manufacturing a semiconductor device according to a conventional all-in-one etching method has had a problem in which, when a plurality of wafers are continuously processed in one and the same chamber, etching characteristics are influenced by deposits at an etching step for to be processed later. Thereby, there have been some problems in which there are caused variations in etching depths of via holes, interconnect trenches, and the like between wafers and within a same wafer.

Moreover, according to the method of manufacturing a semiconductor device, which has been disclosed in Japanese Laid-Open Patent Publication No. 2005-353698, a Cu interconnect is exposed after removing the SiCN film by etching when the SiCN film exists on the underlying interconnect formed of Cu. The Cu interconnect will become a factor interrupting electric conduction because there is caused, for example, oxidation reaction between the interconnect and the above described cleaning gas. Accordingly, the method removing the deposit by using the cleaning gas has not been adopted.

In one embodiment, there is provided a method of manufacturing a semiconductor device having a step in which a substrate to be processed in which a stacked film containing a first insulating film and a second insulating film are formed on or over a semiconductor substrate is arranged in an etching equipment, and the first insulating film and the second insulating film are etched in one and the same etching equipment, wherein the first insulating film is comprised of a nitrogen-containing film, and the second insulating film is comprised of one or more kinds of films selected from a group consisting of an SiOCH film, an SiO₂ film, a methyl silsesquioxane film, a hydrogen silsesquioxane film and a methyl hydrogen silsesquioxane film, and in the step, as both etching gas for the first insulating film and etching gas for the second insulating film, (a) gas including fluorocarbon represented by CxFy (x: an integer from 1 to 6, and y: an integer from 4 to 12), or (b) mixed gas of the fluorocarbon and one or more kinds of gas selected from a group consisting of O₂, Ar and CO, is employed.

In the above method of manufacturing a semiconductor device according to the present invention, the stacked film on or over a substrate to be processed is etched by a combination of a predetermined film and a predetermined etching gas.

Thereby, another same kind of substrate to be processed is carried into the etching equipment after completing the etching step of the substrate to be processed, and the same etching step is executed, and the productivity of the semiconductor device may be improved. That is, as the amount of nitrogen atoms and that of hydrogen atoms, which are included in deposits, are reduced at the etching step, influences by the nitrogen atoms and the hydrogen atoms may be suppressed when the second insulating film in the second and subsequent substrates to be processed are etched. Variations in etching depths of via holes, interconnect trenches, and the like within a same wafer and between wafers can be suppressed, and the productivity of the semiconductor device may be improved.

According to the present invention, influences of deposits, which have adhered to the inner wall of the chamber, may be removed at the etching step. Thereby, there is provided the method of manufacturing a semiconductor device by which variations in etching depths of via holes, interconnect trenches, and the like between wafers and within a same wafer can be suppressed, and an increase in interconnect resistances, that in contact resistances, and the like can be suppressed.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A to 1C are schematic cross-sectional views showing etching steps in a method of manufacturing a semiconductor device according to an embodiment;

FIGS. 2A to 2C are schematic cross-sectional views showing etching steps in the method of manufacturing the semiconductor device according to the embodiment;

FIGS. 3A and 3B are schematic cross-sectional views showing etching steps in the method of manufacturing the semiconductor device according to the embodiment;

FIGS. 4A and 4B are views explaining an object of the present invention;

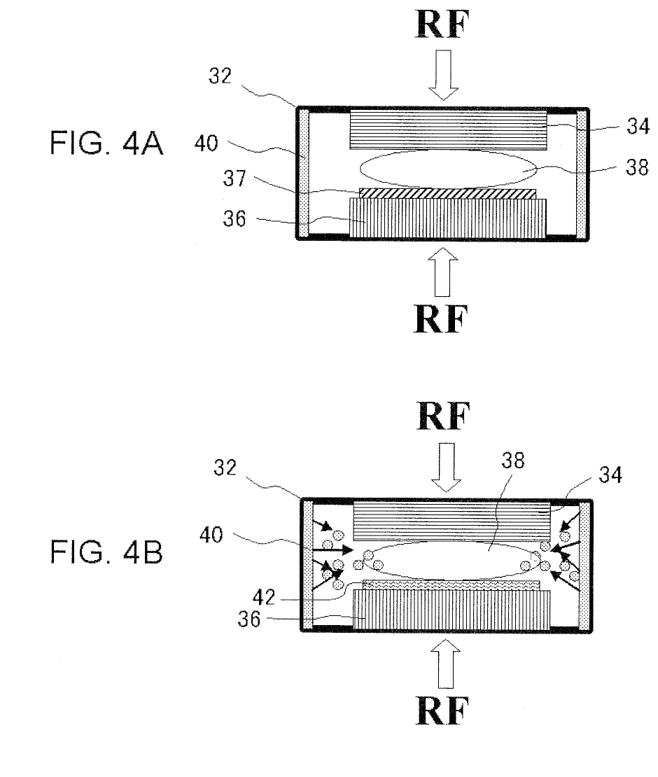

FIG. 5 is a view showing results of an example;

FIGS. 6A and 6B are graphs showing a relation between an etching depth and a pressure, and that between the variation on the wafer surface and the pressure in the method of manufacturing the semiconductor device according to the embodiment;

FIGS. 7A to 7C are graphs showing uniformity on the wafer surface at an etching rate in the method of manufacturing the semiconductor device according to the embodiment;

FIG. 8 is a table representing a relation between plasma power and uniformity on the wafer surface at an etching rate in the method of manufacturing the semiconductor device according to the embodiment;

FIGS. 9A to 9B are graphs showing a relation between the etching depth and the bias power, and that between the variation on the wafer surface and the bias power in the method of manufacturing the semiconductor device according to the embodiment; and

FIGS. 10A to 10C are schematic cross-sectional views showing a cleaning step in conventional etching steps.

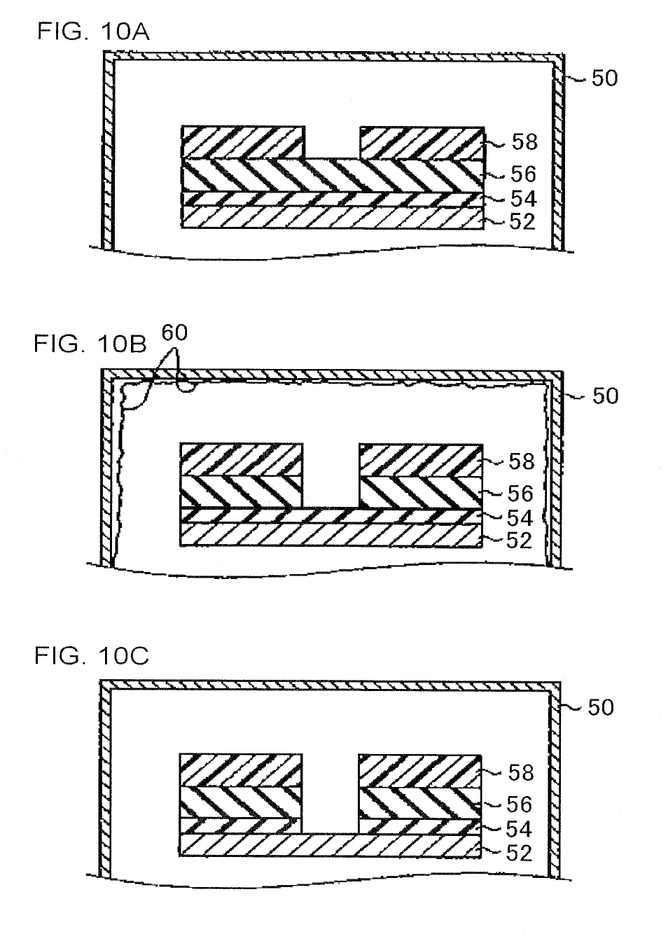

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, embodiments according to the present invention will be explained, with reference to drawings. Here, similar components will be denoted by the same reference numbers in all drawings, and detailed description will not be repeated.

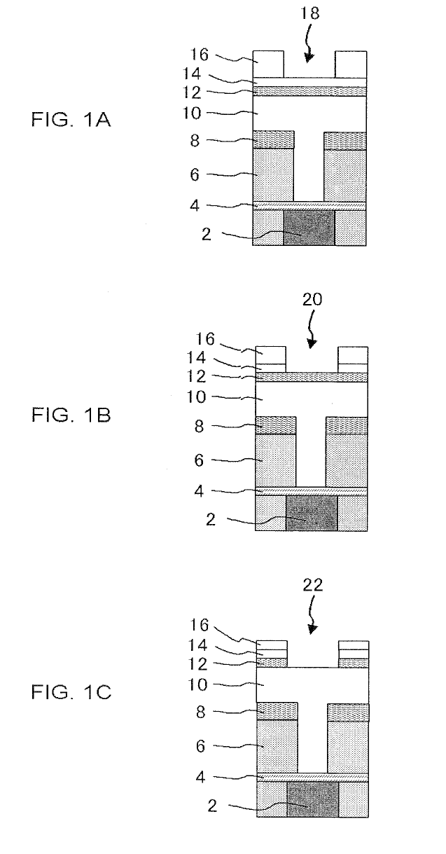

FIGS. 1A to 3B are cross-sectional views showing etching steps sequentially performed in a method of manufacturing a semiconductor device according to the present embodiment. Here, the following steps are successively performed by step switching in one and the same etching equipment.

As shown in FIG. 1A, a substrate to be processed has a structure in which a interconnect layer including an underlying interconnect 2 formed of Cu, a first insulating film (nitrogen-containing stopper film 4), and a second insulating film (interlayer film 6, and Cap film 8) are sequentially stacked on or over a semiconductor substrate (not shown). A via hole is formed through the interlayer film 6 and the Cap film 8, and a resist film 10 is formed in such a way that the above via hole is buried, and, at the same time, the Cap film 8 is covered. Furthermore, a mask film 12 formed of SiO₂, and an antireflection film 14 are formed on the insulating film 10, and, moreover, a resist film 16 having an opening 18 forming an interconnect trench is formed thereon.

In the present embodiment, the nitrogen-containing stopper film 4 is formed of an SiCN film. Moreover, the interlayer film 6 may be formed of: an SiOCH film, a methyl silsesquioxane (MSQ) film; a hydrogen silsesquioxane (HSQ) film; or a methyl hydrogen Silsesquioxane (MHSQ) film. Moreover, the Cap film 8 and the mask film 12 are composed of an SiO₂ film in the present embodiment.

At a first step in etching steps in the method of manufacturing a semiconductor device according to the present embodiment, the antireflection film 14, and, furthermore, the mask film 12 are selectively etched, as shown in FIGS. 1A to 1C, while the resist film 16 having the predetermined opening 18 is used as a mask.

Gas including fluorocarbon represented by CxFy (x: an integer from 1 to 6, and y: an integer from 4 to 12) may be used as etching gas. CF₄, C₂F₆, C₃F₆, C₃F₈, C₄F₈, C₅F₁₀, and the like may be listed as fluorocarbon represented by CxFy. The present embodiment has adopted CF₄.

Mixed gas of the above-described fluorocarbon and one or more kinds of gas selected from a group consisting of O₂, Ar and CO may be used as etching gas in the present embodiment.

In the present embodiment, conditions for plasma etching which is performed a plurality of times are determined from a viewpoint that variations in etching depths of via holes, interconnect trenches, and the like between wafers and within the same wafer are suppressed when interlayer films 6 in the second and subsequent substrates to be processed are etched.

The present embodiment may have a configuration in which only CF₄, or a mixed gas of CF₄ and O₂ is used, a pressure in the etching equipment is from 25 to 55 mTorr, a plasma power is from 100 to 600 W, a bias power is from 150 to 450 W, and a flow rate of O₂/CF₄ is from 0/100 to 11/100.

Hereinafter, details of conditions for etching will be explained.

The pressure may be configured to be from 25 to 55 mTorr.

In the case of a pressure of less than 25 mTorr, the variations in etching depth on the wafer surface becomes about 30 nm or more and the variations in interconnect resistance increases. Moreover, in the case of a pressure exceeding 55 mTorr, an isotropic etching component increases to cause side etching (etching in the horizontal direction) in the nitrogen-containing stopper film 4 at the via bottom, and the filling capability is deteriorated at a later step for Cu filling and the like. Thereby, the condition of from 25 to 55 mTorr may be adopted as a range in which the side etching is not caused in the nitrogen-containing stopper film, and the variations in etching depth on the wafer surface can be suppressed within a preferable range.

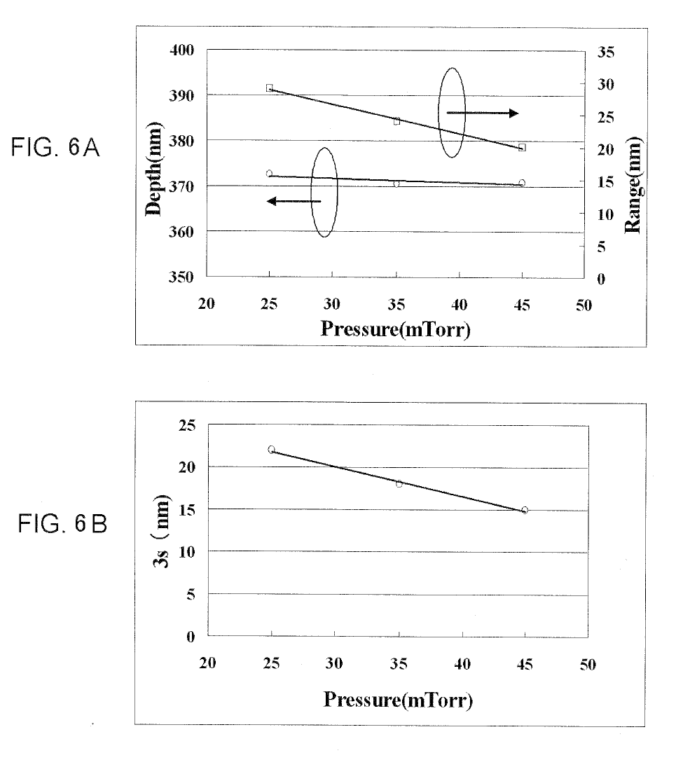

Here, FIGS. 6A and 6B show a relation between an etching depth and an etching pressure, and that between the variation on the wafer surface and the pressure, as experiment results. FIG. 6A shows a relation between a pressure and an etching depth, and that between a pressure and a difference (“Range” denoted in the drawing) between the maximum value and the minimum value of the etching depth. FIG. 6B shows a relation between a pressure and a variation 3 σ of the etching depth.

The plasma power may be configured to be from 100 to 600 W.

The reason is that, when the plasma power exceeds 600 W, the uniformity on the wafer surface is deteriorated partially resulting in a defective opening in the case when the nitrogen-containing stopper film 4 at the via bottom is etched. Moreover, plasma stability is deteriorated into yield loss and productivity loss when plasma power is less than 100 W.

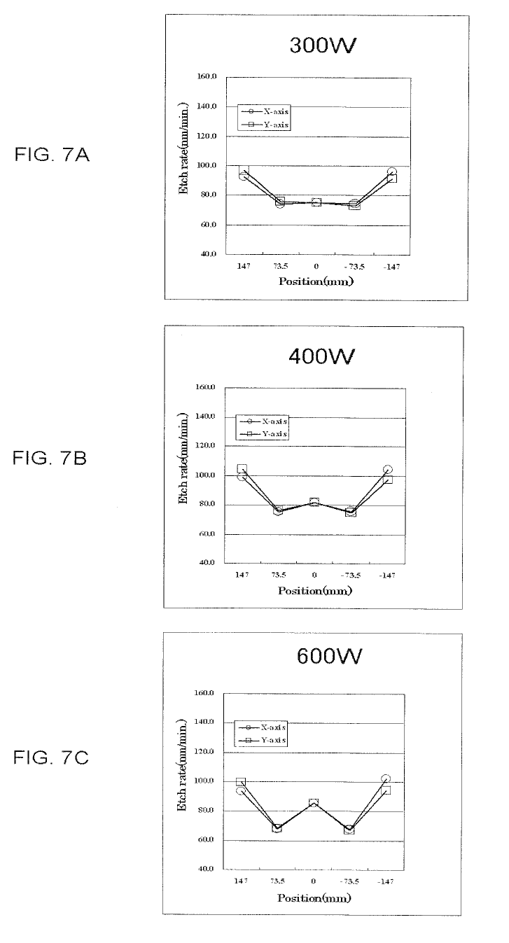

Here, FIGS. 7A, 7B and 7C show uniformity on the wafer surface at an etching rate. FIG. 7A shows results at a plasma power of 300 W, FIG. 7B represents results at a plasma power of 400 W, and FIG. 7C shows results at a plasma power of 600 W. The horizontal axis for the graphs represents a distance from the center of the wafer in the X-axis or Y-axis direction, and the vertical axis represents an etching rate. The diameter of the wafer is 300 mm. The center position of the wafer is represented by “0” on the horizontal axis.

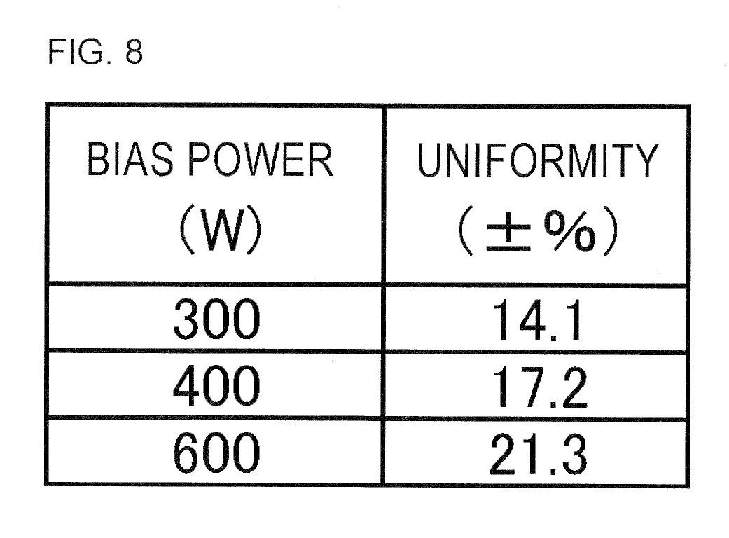

It is found from the drawings that the etching rate has a rising tendency in the outer edge of the wafer. A table shown in FIG. 8 represents a relation between the plasma power and uniformity on the wafer surface at an etching rate (that is, corresponding to the etching depth). Under a condition of from 300 W to 600 W, the uniformity at 300 W is most preferable.

The bias power may be configured to be from 150 to 450 W.

The reason is that, when the bias power is less than 150 W, reduced aeolotropy causes the side etching in the nitrogen-containing stopper film 4 at the via bottom to deteriorate filling capability at a later step for filling via holes with, for example, Cu.

Moreover, the reason is that, when the bias power exceeds 450 W, high energy ions are driven into the underlying interconnect 2 such as Cu, and oxidized substances and deposited substances (reaction product) on the underlying interconnect are abundantly deposited on the underlying interconnect 2 after the nitrogen-containing stopper film 4 at the via bottom is opened to cause defective connection between the upper and the lower interconnects.

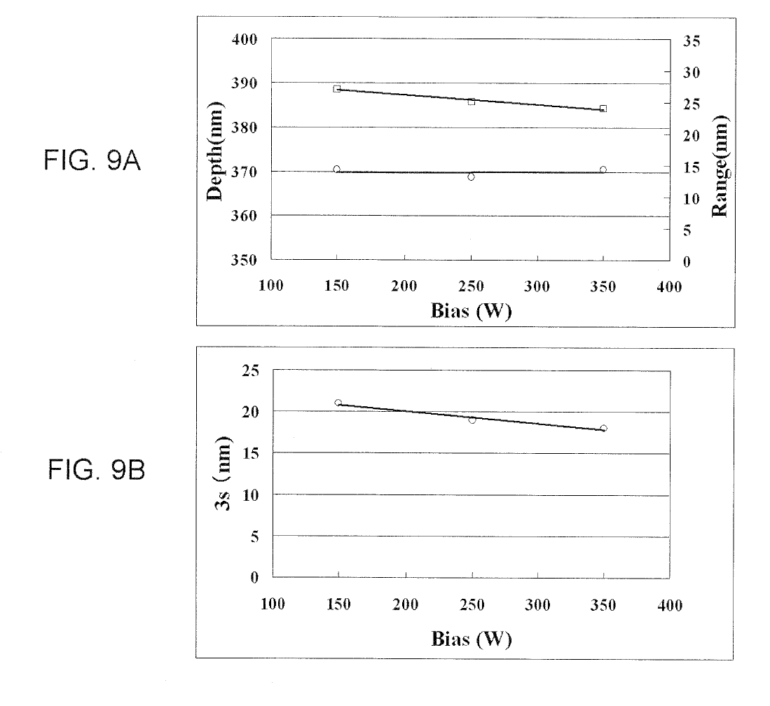

Moreover, as a higher bias voltage causes a variation in trench depth to become smaller, the higher bias voltage is effective for improvement of the interconnect resistance, and, then, a higher bias voltage within a range of from 150 to 450 W, for example, about 350 W may be preferable for use. Here, FIGS. 9A and 9B show a relation between the etching depth and the bias power, and that between the variation on the wafer surface and the bias power, wherein the relations have been obtained as experiment results. FIG. 9A shows a relation between a bias voltage and an etching depth, and that between a bias voltage and a difference (“Range” denoted in the drawing) between the maximum value and the minimum value of the etching depth. FIG. 9B shows a relation between a bias voltage and a variation 3 σ of the etching depth.

The flow rate of O₂/CF₄ may be configured to be from 0/100 to 11/100.

The reason is that, when the flow rate exceeds 11/100, deposited substances is reduced during processing in which the nitrogen-containing stopper film 4 is processed to cause the side etching in the nitrogen-containing stopper film and the burying performance at a later step for burying, for example, Cu is deteriorated. Here, the flow rate of O₂/CF₄ may be configured to be 0/100, that is, only CF₄ may be configured to flow.

There will be explained an example according to the present embodiment. In the example, plasma etching is performed on conditions that, for example, mixed gas of CF₄ and O₂ is used, a pressure is 45 mTorr, plasma power is 300 W, bias power is 150 W, and CF₄: O₂=50:3 (flow rate). Here, the above conditions for plasma etching is one example, and conditions for plasma etching according to the present embodiment are not limited to the above example. The same holds true for the after-described conditions for plasma etching.

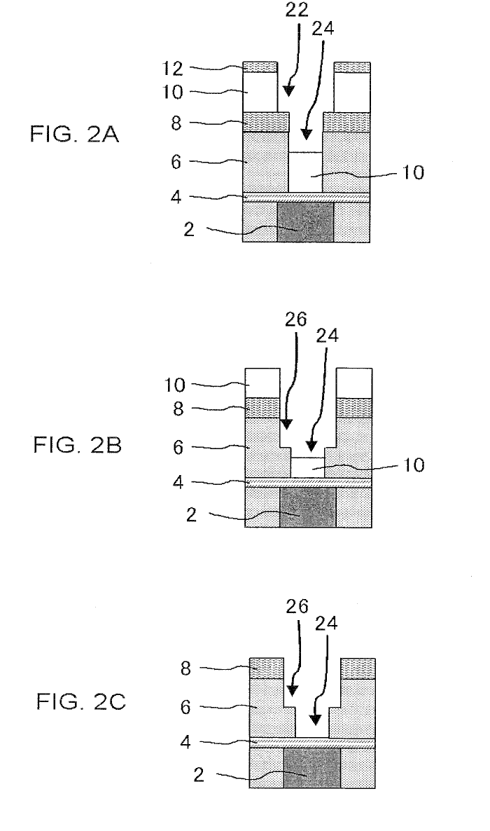

Subsequently, as shown in FIG. 2A, the resist film 16 and the antireflection film 14 on the mask film 12 are removed by etching, and the resist film 10 is selectively etched, using the mask film 12 as a mask. The opening is expanded by the above etching to form an opening 22 in the resist film 10 on the Cap film 8, and, at the same time, a part of the resist film 10 is configured to remain in a via hole 24.

Then, as shown in FIG. 2B, the mask film 12 and a part of the resist film 10 on the Cap film 8 are removed by etching, and the Cap film 8 and the interlayer film 6 are etched, using the above films as a mask. Thereby, an interconnect trench 26 is formed in the Cap film 8 and the interlayer film 6.

Gas including fluorocarbon represented by CxFy (x: an integer from 1 to 6, and y: an integer from 4 to 12) may be used as etching gas. There may be listed CF₄, C₂F₆, C₃F₆, C₃F₈, C₄F₈, C₅F₁₀, and the like as fluorocarbon represented by CxFy. The present embodiment has adopted CF₄.

Mixed gas of the above-described fluorocarbon and one or more kinds of gas selected from a group consisting of O₂, Ar and CO may be used as etching gas in the present embodiment.

There will be explained an example according to the present embodiment. In the example, plasma etching is performed on conditions that, for example, mixed gas of CF₄ and O₂ is used, a pressure is 45 mTorr, plasma power is 300 W, bias power is 150 W, and CF₄: O₂=50:3 (flow rate).

Then, the resist film 10 is completely removed at an ashing step (FIG. 2C). The ashing step has adopted an O₂ ashing process using a low-pressure power region, by which an interlayer film material (low-K material) is impervious to being damaged. The ashing process has been disclosed, for example, in Japanese Laid-Open Patent Publication No. 2004-128313. Furthermore, the nitrogen-containing stopper film 4 is etched, using the Cap film 8 and the upper surface of the interlayer film 6, which is exposed at the lower surface of the interconnect trench 26, as a mask.

Gas including fluorocarbon represented by CxFy (x: an integer from 1 to 6, and y: an integer from 4 to 12) may be used as etching gas. There may be listed CF₄, C₂F₆, C₃F₆, C₃F₈, C₄F₈, C₅F₁₀, and the like as fluorocarbon represented by CxFy. The present embodiment has adopted CF₄.

Mixed gas of the above-described fluorocarbon and one or more kinds of gas selected from a group consisting of O₂, Ar and CO may be used as etching gas in the present embodiment.

There will be explained an example according to the present embodiment. In the example, plasma etching is performed on conditions that, for example, mixed gas of CF₄ and O₂ is used, a pressure is 45 mTorr, plasma voltage is 300 W, a bias voltage is 150 W, and CF₄: O₂=50:3 (flow rate).

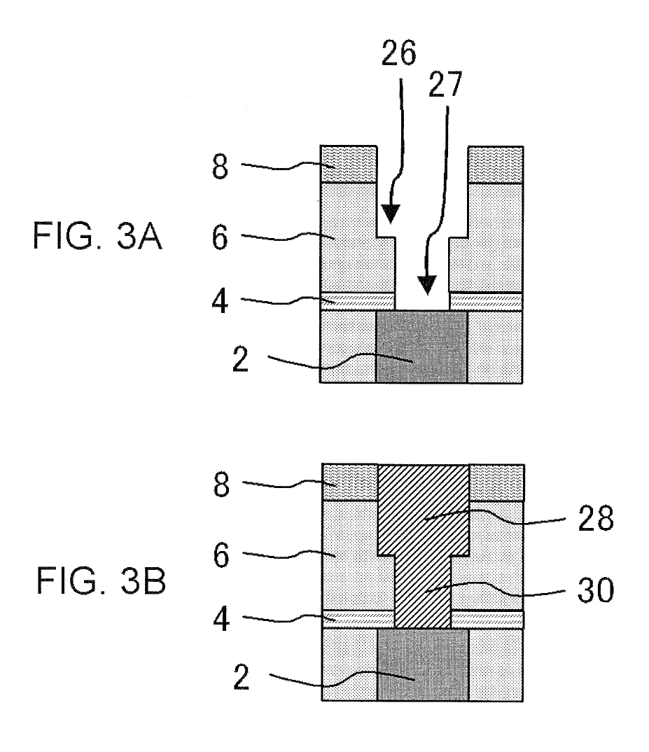

According to the above etching step, a via hole 27 is formed on the underlying interconnect 2 (FIG. 3A).

After completing the etching step, the substrate to be processed is carried out from a chamber in the etching equipment, and a Cu film is formed in such a way that the via hole 27 and the interconnect trench 26 are filled with Cu. Simultaneously, the Cu film is configured to be left only in the via hole 27 and the interconnect trench 26 by a chemical mechanical polishing (CMP) step. Thereby, an upper interconnect 28 and a via plug 30 are formed (FIG. 3B).

Furthermore, usual manufacturing steps are performed to manufacture the semiconductor device according to the present embodiment.

Here, the substrate to be processed is carried out from the chamber in the etching equipment, and, subsequently, another same kind of a substrate to be processed is carried into for the same etching processing.

Hereinafter, effects caused by the above embodiment will be explained.

According to the present embodiment, the amount of nitrogen atoms and that of hydrogen atoms may be reduced at the etching step using the all-in-one etching method, wherein the nitrogen atoms and the hydrogen atoms are included in deposits which have adhered to the inner wall of the chamber. Thereby, there are provided the method of manufacturing a semiconductor device, by which variations in etching depths of via holes, interconnect trenches, and the like between wafers and within a same wafer may be suppressed, and the increase in the interconnect resistances, that in the contact resistances, and the like may be suppressed.

Moreover, the present embodiment may have a configuration in which another same kind of a substrate to be processed is carried into the etching equipment after completing the etching step of the substrate to be processed, and the same etching step is executed.

According to the above embodiment, the productivity of the semiconductor device may be improved. That is, as the amount of the nitrogen atoms and that of the hydrogen atoms, which are included in the deposits, are reduced at the etching step, influences by the nitrogen atoms and the hydrogen atoms may be suppressed when SiOCH films forming interlayer films in the second and subsequent substrates to be processed are etched. Thereby, variations in etching depths of via holes, interconnect trenches, and the like may be suppressed to improve the productivity of the semiconductor device. Furthermore, the influences of the deposits which have adhered to the inner wall of the chamber are suppressed, even if a Cap film formed of SiO₂, and the like are included, to form a pattern as designed.

As described above, the embodiment according to the present invention has bee described, with reference to the drawings. These are the illustrations of the present invention. However, various kinds of configurations except the above one may be adopted.

For example, a single-layer film may be adopted as the second insulating film, though the second insulating film has been configured to be a stacked film including the interlayer film 6 and the Cap film 8 when the present embodiment is explained.

Moreover, the explained embodiment has had a configuration including a step at which the resist film is removed by ashing. However, the nitrogen-containing stopper film 4 and the interlayer film 6 may be etched at one step using the same etching gas. The same etching gas may be used from a viewpoint that the amount of the deposits, which have adhered to the inner wall of the chamber in the etching equipment, is reduced. On the other hand, the kind of the etching gas may be changed from a viewpoint that the nitrogen-containing stopper film 4 is easily removed to improve the process efficiency.

Moreover, the etching step in the dual damascene process has been explained in the present embodiment, and the same may hold true for the etching step in the via plug forming process and the like.

Furthermore, an organic material may be used as the interlayer film 6, and both an inorganic material and an organic material may be also applied to even a porous film, or to even a film with a high film density. A silicon low-k polymer (SiLK) organic material may be listed as an organic material. A porous MSQ film, a porous MHSQ film, or a porous HSQ film may be listed as a porous inorganic material. A semiconductor device of a coming generation, or a semiconductor device of the next generation but one generation, which adopts a smaller effective dielectric constant, has been moving in the direction of introducing holes in an interlayer film for use as a porous film in order to realize a smaller dielectric constant of the film. The present invention may be also applied to the above new-type interlayer material, that is, may contribute to stable production of a coming-generation semiconductor device.

Similarly, an organic material have been adopted for a semiconductor device of the coming generation, or a semiconductor device of the next generation but one generation, because the organic material generally has a smaller dielectric constant, compared with that of an inorganic interlayer material. Accordingly, the present invention may be also applied to the above interlayer materials, that is, may realize stable production with reduced costs for a long time to come.

### EXAMPLE

Etching was performed according to the all-in-one etching method described in FIGS. 1A to 3B under the following conditions according to the following testing method.

### <Testing Method>

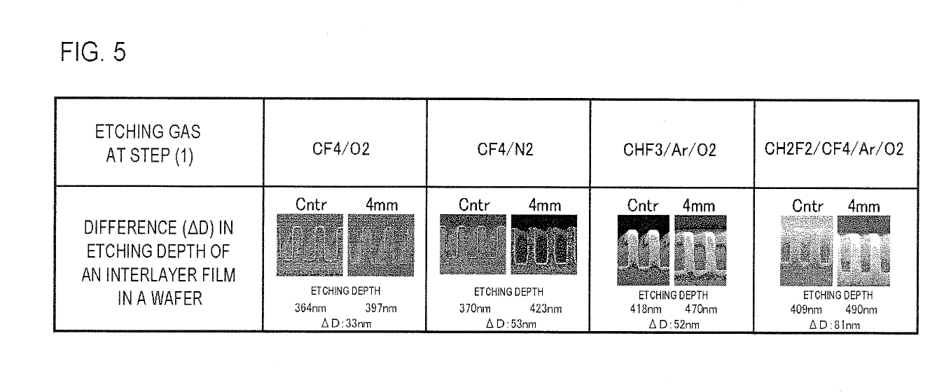

Step (1): Only an Si substrate was mounted in a chamber of an etching equipment, and plasma generation of etching gas described in FIG. 5 was performed.

Step (2): The Si substrate used at the above-described step (1) was taken out, and the substrate with a stacked film was etched under the following conditions according to the etching steps described in FIGS. 1A to 3B. Steps to an ashing step for a resist film 10 were completed, and there was confirmed a difference in etching depth for an interlayer film 6 (SiOCH film) between in the center portion (denoted by “Cntr” in FIG. 5) and in the outer edge (at a position 4 mm inward from the outside edge (denoted by “4 mm” in FIG. 5)) of the wafer. Here, the tests were conducted in a portion in which a via hole like the via hole shown in FIG. 1A was not provided in the interlayer film 6 and a Cap film 8. The results are shown in FIG. 5.

### <Test Conditions>

Underlying interconnect 2: Cu,

Nitrogen containing stopper film 4: SiCN film,

Interlayer film 6: SiOCH film,

Cap film 8: SiO₂,

Mask film 12: SiO₂,

Etching gas: Mixed gas of CF₄ and O₂, and

Etching conditions
Pressure: 45 mTorr,
Plasma power: 300 W,
Bias power: 150 W, and
CF₄: O₂=50:3 (flow rate).

### <Results>

When CF₄/O₂ was used as etching gas at Step (1), there was more suppressed a difference in etching depth for the interlayer film 6 (SiOCH film) between in the center portion and in the outer edge of the wafer as shown in FIG. 5 in comparison with a case in which CF₄/N₂, CHF₃/Ar/O₂, or CH₂F₂/CF₄/Ar/O₂ was used. Accordingly, it was confirmed that, when CF₄/O₂ was used as etching gas, as nitrogen atoms and hydrogen atoms, which had effects on etching steps of the second and subsequent substrates to be processed, were not included in deposits, variations in etching depths of via holes, interconnect trenches, and the like between wafers and within a same wafer were suppressed. Here, when CF₄/Ar, or CF₄/CO was used instead of CF₄/O₂, there was suppressed a difference in etching depth for the interlayer film 6 (SiOCH film) between in the center portion and in the outer edge of the wafer as in the case in which CF₄/O₂ was used.

It is apparent that the present invention is not limited to the above embodiment, and may be modified and changed without departing from the scope and spirit of the invention.

What is claimed is:

1. A method of manufacturing a semiconductor device, having a step in which a substrate to be processed in which a stacked film containing a first insulating film and a second insulating film are formed on a semiconductor substrate is arranged in an etching equipment, and said first insulating film and said second insulating film are etched in one and the same etching equipment,
wherein said first insulating film is comprised of a nitrogen-containing film, and said second insulating film is comprised of one or more kinds of films selected from a group consisting of an SiOCH film, an SiO₂ film, a methyl silsesquioxane film, a hydrogen silsesquioxane film and a methyl hydrogen silsesquioxane film, and
in said step, as both etching gas for said first insulating film and etching gas for said second insulating film,
(a) gas including fluorocarbon represented by CxFy (x: an integer from 1 to 6, and y: an integer from 4 to 12), or
(b) mixed gas of said fluorocarbon and one or more kinds of gas selected from a group consisting of O₂, Ar and CO, is employed.

2. The method of manufacturing a semiconductor device according to claim 1,
wherein another same kind of a substrate to be processed is carried into said etching equipment after completing said etching step, and a step same as said etching step is executed.

3. The method of manufacturing a semiconductor device, according to claim 1,
wherein in said step, said first insulating film and said second insulating film are etched in said one and the same etching equipment under the following conditions,
a pressure in said etching equipment: 25 to 55 mTorr;
plasma power: 100 to 600 W;
bias power: 150 to 450 W; and
a flow rate represented by O₂ gas/fluorocarbon gas: 0/100 to 11/100.

4. The method of manufacturing a semiconductor device, according to claim 1,
wherein said fluorocarbon is CF₄.

5. The method of manufacturing a semiconductor device, according to claim 1,
wherein said first insulating film is comprised of an SiCN film.
